(19) United States
(12) Patent Application Publication
(10) Pub. No.: US 2017/0153994 A1
(43) Pub. Date: Jun. 1, 2017

(54) MASS STORAGE REGION WITH RAM-DISK ACCESS AND DMA ACCESS

(71) Applicant: ROBERT J. ROYER, Jr., Portland, OR (US)

(72) Inventor: ROBERT J. ROYER, Jr., Portland, OR (US)

(21) Appl. No.: 14/954,517

(22) Filed: Nov. 30, 2015

(51) Int. Cl. G06F 13/30; G11C 7/10; G11C 14/00; G06F 3/06

(52) U.S. Cl. CPC G06F 13/30; G06F 3/0688; G06F 3/0655; G06F 3/061; G11C 7/1072; G11C 14/0036; G11C 11/16

(57) ABSTRACT

An apparatus is described that includes a non volatile memory interface to couple to a non volatile random access memory comprising a mass storage region. The apparatus further includes system memory storage logic to process smaller and/or high priority data transfers between the mass storage region and a system memory. The apparatus further includes DMA circuitry to process larger and/or low priority data transfers between the mass storage region and the system memory.

### FIELD OF INVENTION

The field of invention pertains generally to the computing sciences, and, more specifically, to a mass storage region having both RAM-disk access and DMA access.

### BACKGROUND

Computing systems typically include a system memory (or main memory) that contains data and program code of the software code that the system's processor(s) are currently executing. A pertinent bottleneck in many computer systems is the system memory. Here, as is understood in the art, a computing system operates by executing program code stored in system memory. The program code when executed reads and writes data from/to system memory. As such, system memory is heavily utilized with many program code and data reads as well as many data writes over the course of the computing system's operation. Finding ways to speed-up system memory is therefore a motivation of computing system engineers.

### FIGURES

A better understanding of the present invention can be obtained from the following detailed description in conjunction with the following drawings, in which:

FIG. 1 shows a computing system having a multi-level system memory;

FIG. 2 shows an improved computing system memory having a mass storage region in far memory that is accessible through RAM-disk methods and DMA methods;

FIG. 3 shows a more detailed hardware design of the system of FIG. 2;

FIG. 4 show another improved computing system having a region in mass storage that is accessible through RAM-disk methods and DMA methods;

FIG. 5 shows a method that can be performed by either of the systems of FIGS. 2 and 4;

FIG. 6 shows an exemplary computing system.

### DETAILED DESCRIPTION

An area where system designers seek to speed up system performance is mass storage and/or the transfers that occur between mass storage and system memory. Effective speed up of a computing system's mass storage function (e.g., which are traditionally implemented with a disk drive or solid state drive (SSD)) has been accomplished with DMA transfers between mass storage and system memory, and/or, “RAM-disk” configurations.

In the case of DMA transfers, often during the operation of a computer program, data and/or code that is not in system memory is needed by the software program. In response, the system will transfer the needed data and/or code from mass storage into system memory by way of a DMA transfer. DMA transfers evolved as a mechanism to reduce CPU overhead. Whereas in older systems a transfer between mass storage and system memory was handled through direct oversight and corresponding instruction execution by the CPU, by contrast, DMA transfers emerged in order to remove the CPU of this burden. Instead, the oversight and control of the transfer between mass storage and memory is handled by a DMA engine. The logic circuitry of the DMA engine essentially replaces the data transfer operations that used to be performed by the CPU.

A DMA transfer includes the creation by the DMA engine of a logical path between a mass storage device and the system memory so that large sector(s) of code/data read from mass storage can be quickly streamed into system memory, or, sector(s) worth of code/data read from system memory can be quickly streamed into mass storage. Here, the DMA engine will essentially perform operations to set-up the logical path between the mass storage device and system memory. Again, the setup activity by the DMA engine saves the CPU from having to organize/oversee the data transfer itself.

A RAM-disk operation is an implementation of a mass storage function within system memory DRAM devices. Here, as traditional mass storage devices such as disk drives or solid state disk devices have longer latencies than traditional DRAM memory devices, in order to speed up the operation of a system's mass storage, a mass storage function is physically implemented with DRAM system memory resources. RAM-disk accesses, however, do not make use of a DMA engine and instead are accessed in the same manner that system memory reads/writes are performed. That is, in order to perform a RAM-disk access, the CPU issues read/write requests to a main memory controller. As a consequence, the CPU consumes cycles executing instructions overseeing the transfer of data between system memory and the RAM-disk storage region. As such, a DMA transfer is not a feature of a RAM-disk access. Additionally, physical accesses to/from the RAM-disk storage medium are made at cache line granularity (rather than sector granularity) and therefore, again, physically resemble system memory accesses rather than mass storage accesses.

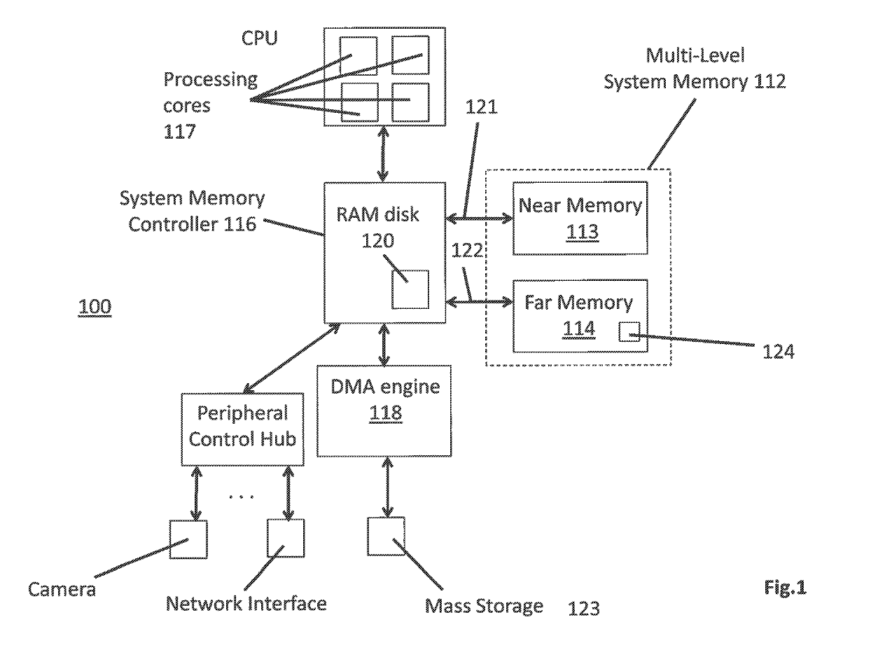

One of the ways to speed-up system memory without significantly increasing power consumption is to have a multi-level system memory. FIG. 1 shows an embodiment of a computing system 100 having a multi-tiered or multi-level system memory 112. According to various embodiments, a faster near memory 113 may be utilized as a memory side cache.

In the case where near memory 113 is used as a memory side cache, near memory 113 is used to store data items that are expected to be more frequently called upon by the computing system. The near memory cache 113 has lower access times than the lower tiered far memory 114 region. By storing the more frequently called upon items in near memory 113, the system memory 112 will be observed as faster because the system will often read items that are being stored in faster near memory 113.

According to some embodiments, for example, the near memory 113 exhibits reduced access times by having a faster clock speed than the far memory 114. Here, the near memory 113 may be a faster, volatile system memory technology (e.g., high performance dynamic random access memory (DRAM)) or faster non volatile memory. By contrast, far memory 114 may be either a volatile memory technology implemented with a slower clock speed (e.g., a DRAM component that receives a slower clock) or, e.g., a non volatile memory technology that is inherently slower than volatile/DRAM memory or whatever technology is used for near memory.

For example, far memory 114 may be comprised of a non volatile byte addressable random access memory technology such as, to name a few possibilities, a three dimensional crosspoint memory, a phase change based memory, a ferro-electric based memory (e.g., FRAM), a magnetic based memory (e.g., MRAM), a spin transfer torque based memory (e.g., STT-RAM), a resistor based memory (e.g., ReRAM), a Memristor based memory, universal memory, Ge2Sb2Te5 memory, programmable metallization cell memory, amorphous cell memory, Ovshinsky memory, etc.

Such non volatile random access memories technologies can have some combination of the following: 1) higher storage densities than DRAM (e.g., by being constructed in three-dimensional (3D) circuit structures (e.g., a three dimensional crosspoint circuit structure)); 2) lower power consumption densities than DRAM (e.g., because they do not need refreshing); and/or, 3) access latency that is slower than DRAM yet still faster than traditional non-volatile memory technologies such as FLASH. The latter characteristic in particular permits a non volatile memory technology to be used in a main system memory role rather than a traditional mass storage role (which is the traditional architectural location of non volatile storage). DRAM devices, whether implemented as near memory, far memory or system memory generally may also be fitted with battery back-up support in order to exhibit non-volatile behavior.

Regardless of whether far memory 114 is composed of a volatile or non volatile memory technology, in various embodiments, far memory 114 acts as a system memory in that it supports finer grained data accesses (e.g., cache lines) rather than larger sector based accesses associated with traditional, non volatile mass storage (e.g., solid state drive (SSD), hard disk drive (HDD)), and/or, otherwise acts as an (e.g., byte) addressable memory that the program code being executed by processor(s) of the CPU operate out of.

Because near memory 113 acts as a cache, near memory 113 may not have its own individual addressing space. Rather, far memory 114 can include the individually addressable memory space of the computing system's main memory. In various embodiments near memory 113 acts as a cache for far memory 114 rather than acting a last level CPU cache. Generally, a CPU level cache is able to keep cache lines across the entirety of system memory addressing space that is made available to the processing cores 117 that are integrated on a same semiconductor chip as the memory controller 116. Additionally a CPU level cache receives entries after a higher level cache evicts content that is pushed down to the CPU level cache. By contrast, a memory side cache can receive entries as a consequence of what is being called up from system memory rather than receiving entries as a consequence of a higher level cache evictions.

For example, in various embodiments, system memory is implemented with dual in-line memory module (DIMM) cards where a single DIMM card has both DRAM and (e.g., emerging) non volatile memory chips disposed in it. The DRAM chips act as an on board cache for the non volatile memory chips on the DIMM card. The more frequently accessed cache lines of any particular DIMM can be found on that DIMM card's DRAM chips rather than its non volatile memory chips. Given that multiple DIMM cards are typically plugged into a working computing system and each DIMM card is given a section of the system memory addresses made available to the processing cores 117 of the semiconductor chip that the DIMM cards are coupled to, the DRAM chips are acting as a cache for the non volatile memory that they share a DIMM card with rather than a last level CPU cache.

In other configurations, DIMM cards having only DRAM chips may be plugged into a same system memory channel (e.g., a DDR channel) with DIMM cards having only non volatile system memory chips. In some cases, the more frequently used cache lines of the channel will be found in the DRAM DIMM cards rather than the non volatile memory DIMM cards. Thus, again, because there are typically multiple memory channels coupled to a same semiconductor chip having multiple processing cores, the DRAM chips are acting as a cache for the non volatile memory chips that they share a same channel with rather than as a last level CPU cache.

In yet other possible configurations or implementations, a DRAM device on a DIMM card can act as a memory side cache for a non volatile memory chip that resides on a different DIMM and/or is plugged into a different channel than the DIMM having the DRAM device. Although the DRAM device may potentially service the entire system memory address space, entries into the DRAM device are based in part from reads performed on the non volatile memory devices and not just evictions from the last level CPU cache. As such the DRAM device can still be characterized as a memory side cache.

In yet other embodiments, near memory 113 may act as a CPU level cache rather than a memory side cache, and/or, may be allocated with its own system memory addressing space to effectively behave, e.g., as a higher priority region of system memory (e.g., more important data is put in the faster near memory addressing space of system memory).

Although the above examples referred to packaging solutions that included DIMM cards, it is pertinent to note that this is just one example and other embodiments may use other packaging solutions. For example, to name just a few, stacked chip technology (e.g., one or both of DRAM and non volatile memory stacked on a large system-on-chip having multiple CPU cores and a main memory controller, etc.), one or more DRAM and non volatile memories integrated on a same semiconductor die or at least within a same package as a CPU die containing processing core(s) (e.g., in a multi-chip module, etc.).

As observed in FIG. 1 the system includes a traditional mass storage device 123 such as a hard disk drive and/or a solid state drive (SSD) and an associated DMA engine 118 for managing DMA transfers between system memory 112 and mass storage 123.

The system of FIG. 1 also includes RAM-disk logic circuitry 120 to enable the existence of a RAM-disk region 124 within far memory 114. As described in the background, sectors worth of information are effectively written into the RAM-disk region 124 at cache line granularity without the use of the DMA engine 118. The CPU executes cycles in order to perform the transfers between the RAM-disk region 124 and system memory (notably RAM-disk region 124 is not considered to be a part of system memory 112, but rather, a mass storage device). RAM-disk logic circuitry 120 is designed to mimic the request/response protocol of a mass storage device so that the CPU can operate as if it were communicating with a mass storage device.

A noticeable advantage of keeping a RAM-disk region 124 in non volatile far memory 114 is that the region 124 is non volatile. In prior art RAM-disk solutions that implement a RAM-disk region in volatile DRAM, a “write-through” process is typically enabled whereby, commensurate with any writing of data into the DRAM based RAM-disk, the same data is also written to non volatile mass storage. Here, in order to “guarantee” that the RAM-disk behaves akin to an actual mass storage device, the system should be able to expect that any write to the RAM-disk will be able to survive a power-down event. As such, a copy of any data written to the volatile RAM-disk is also written into mass storage. Implementing a RAM-disk region 124 in non volatile far memory 114 as observed in FIG. 1, by contrast, permits the system to not implement a write-through process and thereby avoid the associated additional internal system traffic overhead.

Although not depicted in FIG. 1, conceivably a same or other RAM-disk logic circuitry within the memory controller 116 could be instantiated that implements a traditional RAM-disk region in volatile, DRAM near memory 113. As part of implementing a RAM-disk region in near memory 112 the system would ideally also include a write through process to, e.g., far memory 114 (either region 124 or some other region within far memory) or to deeper mass storage 123.

Recalling that the DMA engine 118 saves the CPU from executing cycles in order to perform a data transfer between system memory 112 and mass storage 123 while RAM-disk accesses do not save the CPU from executing such cycles, it follows that the DMA engine 118 may be better suited for certain types of system memory/storage transfers while, at the same time, RAM-disk accessing may be better suited for other types of data memory/storage transfers.

Specifically, although RAM-disk transfers consume CPU cycles, under certain conditions it may exhibit lower latency because it is essentially a same/similar access as faster system memory access. Additionally, no time is consumed setting up a DMA path, queuing delay through large DMA queuing structures is avoided, etc. Thus, RAM-disk transfers are more efficient at least for smaller data transfers (e.g., at one extreme, one small sector of information).

By contrast, for these same reasons, a DMA transfer should be more efficient for large transfers of data between system memory and mass storage (e.g., at the other extreme, a plurality of large sectors). Here, if the RAM-disk approach is used to transfer a large amount of data between system memory and a RAM-disk, a large number of CPU cycles will be consumed. Additionally, a DMA transfer may make use of large queuing structures to more efficiently/natively handle large data transfers.

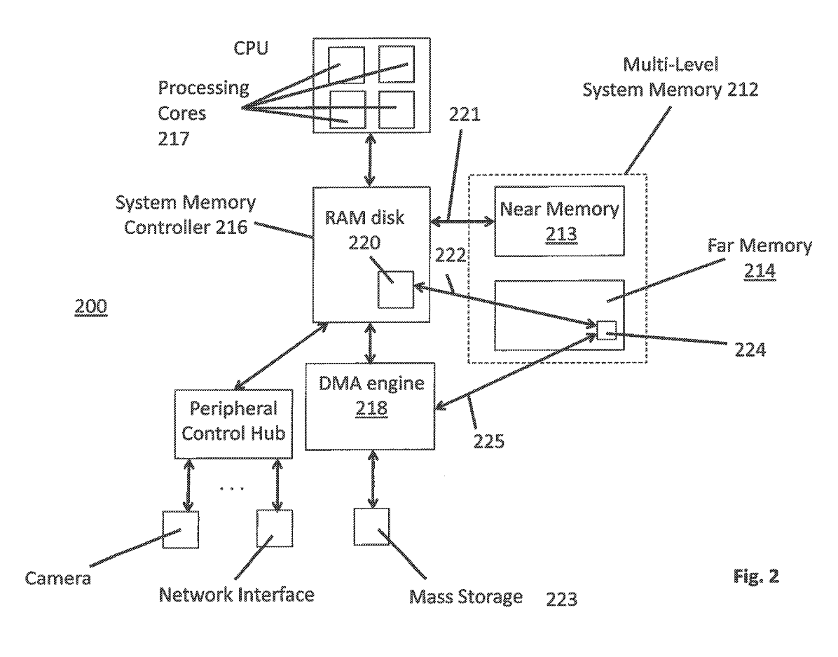

FIG. 2 presents a new type of mass storage approach that keeps a mass storage region 224 in far memory 214 as described above in FIG. 1, but also where the region 224 is accessible through either RAM-disk transfer methods or DMA transfer methods depending on the characteristics of the transfer between the storage region 224 and system memory 212. Specifically, RAM-disk transfer methods, as represented by data flow 222, are used to access the storage structure 224 for smaller sized data transfers and/or higher priority data transfers. By contrast, DMA transfer methods, as represented by data flow 225, are utilized to access the storage structure 224 for larger sized data transfers and/or lower priority data transfers.

Here, the cost of executing CPU cycles is not high in the case of smaller data transfers (a relatively smaller number of CPU cycles are executed). Additionally, accessing the storage medium more quickly through the faster system memory-like access is appropriate in the case of high priority data transfers. By contrast, the elimination of CPU cycles achieved through DMA methods is more beneficial in the case of large data transfers (large data transfers will consume too many CPU cycles if a RAM-disk approach is used). Additionally, any enhanced latency or propagation/queuing delay resulting from a DMA approach is not a significant concern in the case of low priority data transfers.

Note that region 224, although located in far memory 214, is not a component of system memory 212, but rather, is viewed as a mass storage component of the system. In operation, according to one or more embodiments of the system 200, a storage driver of the system receives a request to transfer at least a sector's worth of information from system memory 212 into the storage region 224. The storage driver may be implemented entirely in software (e.g., as a plug-in to an operating system instance), firmware, hardware or any combination thereof.

The storage driver then analyzes characteristics of the transfer, such as its size (how many sectors and/or sector size). If the transfer is characterized as having a smaller size and/or being a higher priority transfer, the driver executes program code (and/or causes program code to be executed) that causes the CPU to execute instructions to manager the transfer consistent with RAM-disk accessing methods. As such, the CPU directs the movement or copying of cache lines from system memory 212 into the region 224. Such movement or copying can be accomplished, for instance, by issuing memory read request instructions to the main memory controller 216 for each of the cache lines to be read from system memory and likewise issuing memory write request instructions to region 224 for each of the cache lines.

By contrast, if the transfer is characterized as having a larger size and/or being a lower priority transfer, the driver writes to register space of the DMA engine 218 to identify the transfer to the DMA engine 218 and/or passes the transfer request through a peripheral mass storage interface (e.g., PCIe or NVMe). In response, the DMA engine 218 sets up a logical read path with the memory controller 216 to read a stream of cache lines from system memory. The DMA engine 218 recognizes a combination of the cache lines as a complete sector and causes the stream of information to flow through the memory controller 216 and be written into region 224. Depending on implementation, the information may be physically written into region 224 as a stream of cache lines, or, as a sector of information. If the later, in one embodiment the logical path between system 212 and the storage region 224 may include logic circuitry to convert a stream of cache lines into a sector of data.

Whether the transfer is effected through RAM-disk transfer methods or DMA transfer methods, in various embodiments, once the information is successfully transferred to storage region 224 from system memory 212, the cache lines in system memory 212 where the information was originally kept may be flushed or subsequently written over. Additionally, a write through to another (e.g., deeper) mass storage device such as mass storage device 223 is not necessary because region 224 is non volatile.

Similarly, in the opposite direction, a storage driver of the system may receive a request to transfer one or more sectors of information from the storage region 224 into system memory 212. In response, the storage driver analyzes the transfer based on its size and/or priority level and determines whether the transfer should be processed according to RAM-disk methods or DMA methods. If the former, the driver causes the CPU to execute cycles to effect the transfer. If the latter, the driver engages the DMA transfer engine 218 to effect the transfer. Conceivably, after the transfer is complete, if the transfer is made to a non volatile far memory region 214 of system memory, the storage region 224 may be flushed or written over because the data that was just transferred is still being kept by non volatile memory and will not be lost in the case of a power down.

In one embodiment, if the information being called up from region 224 for transfer into system memory 212 was previously transferred from system memory 212 and written into region 224 as a stream of cache lines, the information is read from region 224 as a stream of cache lines and forwarded to system memory. Likewise, if the information was previously stored into region 224 as a sector at the concluding end of a transfer from system memory 212, the information is physically read back from region 224 as a sector and formulated back into a stream of cache lines for storage into system memory 212. Here, the pathway from storage region 223 to system memory 212 may include logic circuitry to perform the convert a sector of information into a stream of cache lines.

In alternate or combined embodiments, rather than a driver determining which type of transfer type is appropriate, another system component makes the determination. For example, an operating system instance may make the decision as to what transfer is appropriate and include an indication of the transfer type in the request that is issued to the storage driver. Alternatively or in combination, a hardware component of the system may make the decision (e.g., a host controller having a DMA engine).

In various embodiments, multiple regions like region 224 may form the entire mass storage resources of the system. As such, another separate mass storage device such as storage device 223 is not needed and therefore may not be present in the system. In yet other embodiments, separate deeper storage such as storage device 223 may remain in the system.

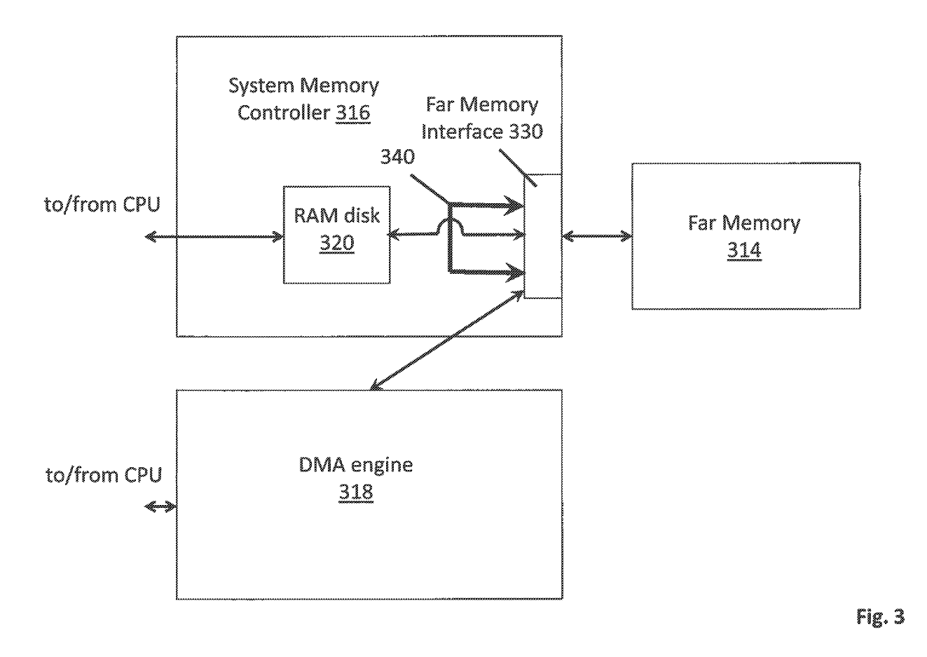

FIG. 3 shows a closer zoom-in of an embodiment of a hardware design for implementing the storage region 224 of FIG. 2. As observed in FIG. 3, the system memory controller 316 includes RAM-disk logic circuitry 320 to mimic the behavior of a mass storage device so that the CPU will think it is communicating with a mass storage device while it is executing RAM-disk transfer instructions. In an embodiment, the RAM-disk logic circuitry 320 effectively implements the host side of a storage interface such as SATA, NVMe, etc. Again, because logic 320 is used for RAM-disk accesses in which the CPU oversees/executes the transfer, RAM-disk logic circuitry 320 in various embodiments does not include or use any DMA transfer logic. Alternatively, the function of RAM-disk logic circuitry 320 can be partially or wholly implemented in software, e.g., as a software driver that presents a mass storage interface to an operating system or virtual machine monitor (VMM) instance.

In the simplest case where both the system memory end of the transfer and the storage region end of the transfer are within far memory 314, the cache lines being transferred according to the RAM-disk transfer are read through an interface 330 to the far memory 314 and are written to the storage region through the same interface 330. As such the logical data path follows a loop-back 340 with the far memory interface 330. If sectors are physical stored in the storage region, the loopback path 340 may further include circuitry to convert cache lines into a sector and/or circuitry convert a sector into cache lines.

Likewise, the DMA engine 318 is coupled to communicate with the CPU and/or driver and/or OS (through the CPU) to perform communications regarding the set-up and tear-down of the logical data path between the storage region and system memory (e.g., an acknowledgement that the logical path exists, an acknowledgement that the logical path has been torn down, etc). The DMA engine 318 is also coupled to the far memory interface 330 so that the DMA engine 318 can organize/control the transfers between system memory and the storage region. Again, in the simplest case where both the system memory end of the transfer and the storage region end of the transfer are within far memory 314, the cache lines being transferred according to the DMA transfer are read through an interface 330 to the far memory 314 and are written to the storage region through the same interface 330. As such the logical data path follows a loop-back 340 with the far memory interface 330. If sectors are physical stored in the storage region, the loopback path 340 may further include circuitry to convert cache lines into a sector and/or circuitry convert a sector into cache lines.

According to one embodiment, all transfers from the storage region to system memory conform to the aforementioned simplest case. That is, all cache lines written into system memory are written into far memory and none of the cache lines are written into near memory cache or other level of the multi-level system memory. In other embodiments, all the cache lines being written into system memory are required to be written into far memory, but, versions of the cache lines may also be entered into near memory cache.

For transfers from system memory to the storage region, in an embodiment, all the cache lines being read from system memory must be read from far memory. As such, any versions of these cache lines that are in near memory cache must first be evicted from near memory cache and entered into far memory before the transfer is permitted to occur. In another embodiment, a read request for each cache line is effectively provided to system memory and, if the cache line is found in near memory cache (or any higher level of the memory), that version of the cache line is transferred to the storage region. Cache lines that do not have a cached version in near memory cache or higher system memory level are simply read from far memory.

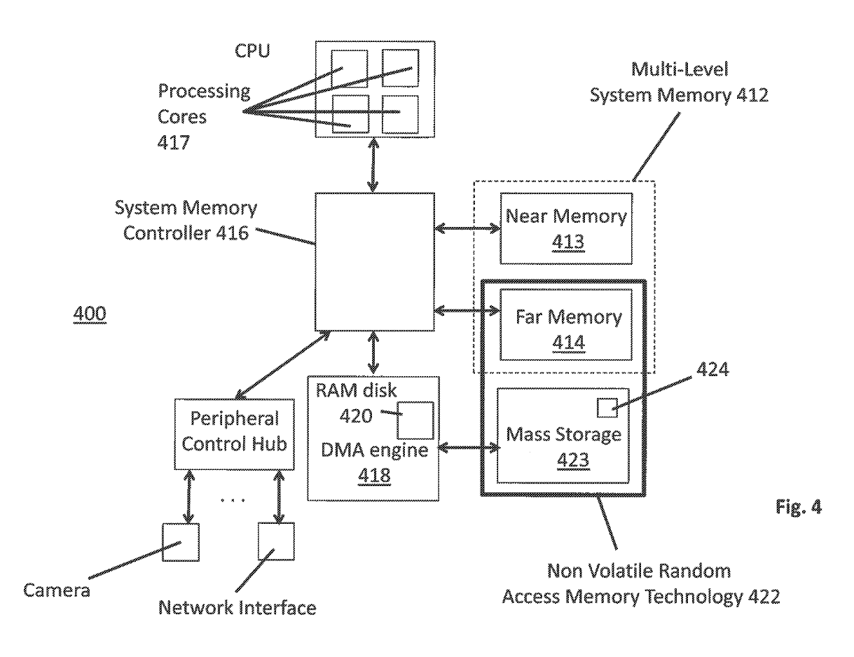

FIG. 4 shows another embodiment having a special mass storage region 424 that is capable of being accessed according to RAM-disk transfer methods or DMA transfer methods depending on the characteristic of the transfer. However, unlike the approach of FIG. 2 where the special mass storage region is located in a far memory level of system memory, by contrast, the special mass storage region 424 of FIG. 4 is a component of the mass storage resources 423 of the system which themselves are implemented with a non volatile emerging random access memory technology 422 (such as the same memory technology that the far memory 414 is composed of). The far memory 414 and non volatile random access memory technology 422 can be implemented as any or a combination of those memory technologies described with regard to far memory 114.

Here, the system operates similar to the system described above with respect to FIG. 2 except that DMA transfers to storage region 424 are performed naturally since the storage region 424 is already a component of the system's mass storage resources. The DMA engine 418 or other interface logic of mass storage 423, however, is enhanced to include RAM-disk logic circuitry 420 to support CPU execution of instructions that directly write/read to/from the special storage region.

In one embodiment, the entire mass storage region 423, or at least large segments of it, is composed of multiple special storage regions so that much of system mass storage can be accessed by RAM-disk transfer methods or DMA transfer methods depending on the nature of their respective transfers. In another or combined embodiment, along with one or more special storage regions in mass storage 423, there also exist special storage regions in far memory (e.g., the approaches of both FIG. 2 and FIG. 3 are combined into a same system).

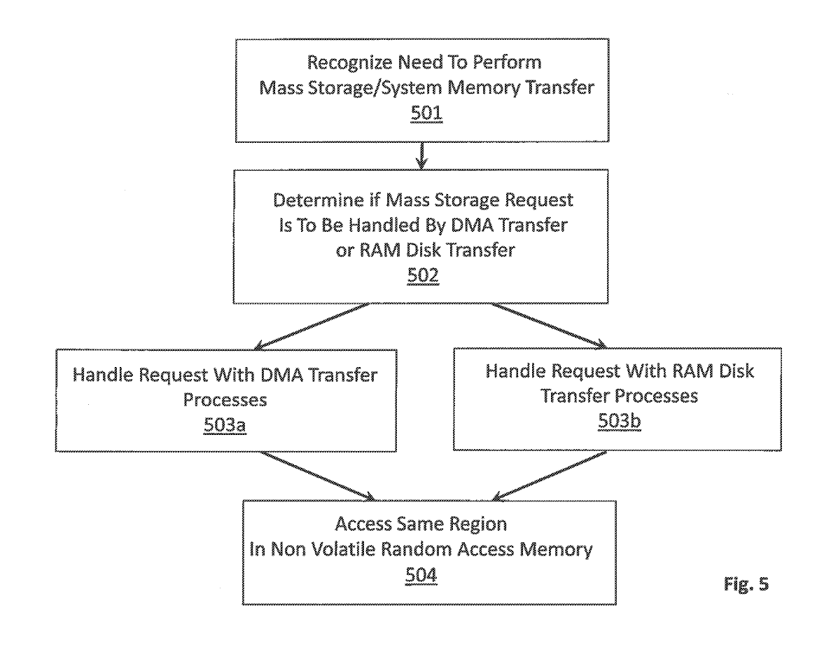

FIG. 5 shows a methodology performed by a mass storage device driver or other one or more functions of a computing system as described above. As observed in FIG. 5 the methodology includes recognizing a need to transfer information between system memory and mass storage 501. In response, a determination is made as to whether the transfer should be handled with RAM-disk transfer methods or DMA transfer methods 502. The transfer is then made according to the determined transfer type 503a, 503b. Noticeably, the same physical storage resource is accessed irrespective of which transfer method is chosen 504.

It is pertinent to recognize that although the above discussion has emphasized use of the term “RAM-disk”, other types of storage functions besides “RAM-disk” may be implemented in system memory that use standard system memory access techniques (e.g., a memory mapped file). As such, the teachings above may be more generally applicable to solutions that include a “system memory storage” function. Additionally, the above described RAM-disk logic circuitry, or any system memory storage logic circuitry, can also be implemented with any of program code, micro-code or firmware. As such, the term “system memory storage logic” is used to refer to any hardware, program code or combination thereof used to implement a system memory storage function.

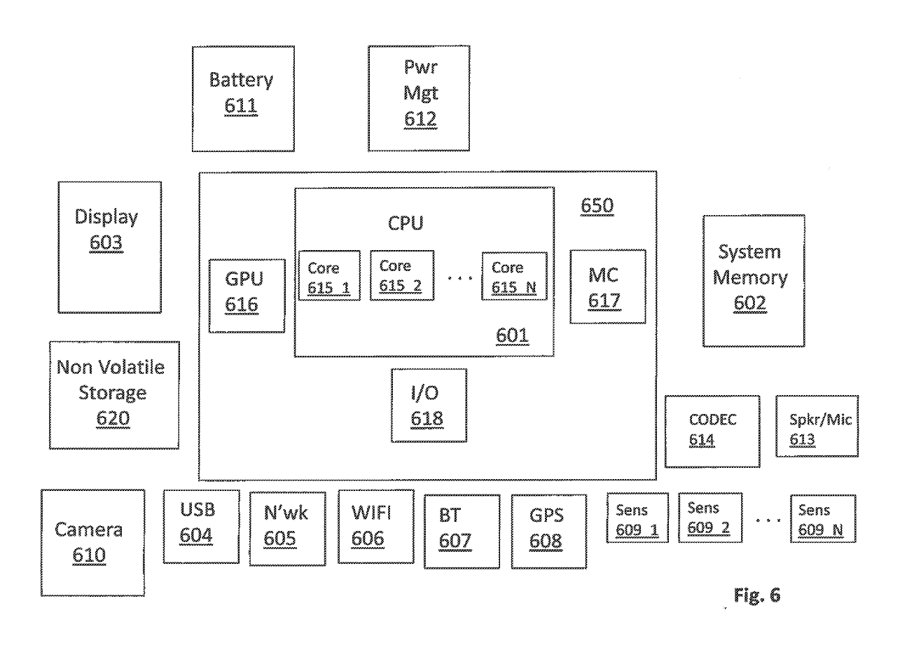

FIG. 6 shows a depiction of an exemplary computing system 600 such as a personal computing system (e.g., desktop or laptop) or a mobile or handheld computing system such as a tablet device or smartphone, or, a larger computing system such as a server computing system. As observed in FIG. 6, the basic computing system may include a central processing unit 601 (which may include, e.g., a plurality of general purpose processing cores and a main memory controller disposed on an applications processor or multi-core processor), system memory 602, a display 603 (e.g., touchscreen, flat-panel), a local wired point-to-point link (e.g., USB) interface 04, various network I/O functions 605 (such as an Ethernet interface and/or cellular modem subsystem), a wireless local area network (e.g., WiFi) interface 606, a wireless point-to-point link (e.g., Bluetooth) interface 607 and a Global Positioning System interface 608, various sensors 609_1 through 609_N (e.g., one or more of a gyroscope, an accelerometer, a magnetometer, a temperature sensor, a pressure sensor, a humidity sensor, etc.), a camera 610, a battery 611, a power management control unit 612, a speaker and microphone 613 and an audio coder/decoder 614.

An applications processor or multi-core processor 650 may include one or more general purpose processing cores 615 within its CPU 601, one or more graphical processing units 616, a memory management function 617 (e.g., a memory controller) and an I/O control function 618. The general purpose processing cores 615 typically execute the operating system and application software of the computing system. The graphics processing units 616 typically execute graphics intensive functions to, e.g., generate graphics information that is presented on the display 603. The memory control function 617 interfaces with the system memory 602. The system memory 602 may be a multi-level system memory such as the multi-level system memory discussed at length above. The system memory 602 and/or non volatile mass storage 620 may include a mass storage region capable of being accessed by either RAM-disk transfer methods or DMA transfer methods as discussed at length above.

Each of the touchscreen display 603, the communication interfaces 604-607, the GPS interface 608, the sensors 609, the camera 610, and the speaker/microphone codec 613, 614 all can be viewed as various forms of I/O (input and/or output) relative to the overall computing system including, where appropriate, an integrated peripheral device as well (e.g., the camera 610). Depending on implementation, various ones of these I/O components may be integrated on the applications processor/multi-core processor 650 or may be located off the die or outside the package of the applications processor/multi-core processor 650.

Embodiments of the invention may include various processes as set forth above. The processes may be embodied in machine-executable instructions. The instructions can be used to cause a general-purpose or special-purpose processor (e.g., CPU core, digital signal processor (DSP)) to perform certain processes. Alternatively, these processes may be performed by specific hardware components that contain hardwired logic for performing the processes, or by any combination of software or instruction programmed computer components or custom hardware components, such as an application specific integrated circuit (ASIC), programmable logic device (PLD) circuitry, field programmable gate array (FPGA), etc..

Elements of the present invention may also be provided as a machine-readable medium for storing the machine-executable instructions. The machine-readable medium may include, but is not limited to, floppy diskettes, optical disks, CD-ROMs, and magneto-optical disks, FLASH memory, ROMs, RAMs, EPROMs, EEPROMs, magnetic or optical cards, propagation media or other type of media/machine-readable medium suitable for storing electronic instructions. For example, the present invention may be downloaded as a computer program which may be transferred from a remote computer (e.g., a server) to a requesting computer (e.g., a client) by way of data signals embodied in a carrier wave or other propagation medium via a communication link (e.g., a modem or network connection).

In the foregoing specification, the invention has been described with reference to specific exemplary embodiments thereof. It will, however, be evident that various modifications and changes may be made thereto without departing from the broader spirit and scope of the invention as set forth in the appended claims. The specification and drawings are, accordingly, to be regarded in an illustrative rather than a restrictive sense.

1. An apparatus, comprising:
a non volatile memory interface to couple to a non volatile random access memory comprising a mass storage region;
system memory storage logic to process smaller and/or high priority data transfers between said mass storage region and a system memory; and,
DMA circuitry to process larger and/or low priority data transfers between said mass storage region and said system memory.

2. The apparatus of claim 1 wherein said non volatile memory interface comprises a system memory interface.

3. The apparatus of claim 2 wherein said non volatile random access memory comprises a system memory region.

4. The apparatus of claim 1 wherein said non volatile memory interface comprises a mass storage interface.

5. The apparatus of claim 1 wherein said DMA circuitry comprises a DMA engine.

6. The apparatus of claim 1 wherein said system memory storage logic comprises circuitry to mimic a mass storage device.

7. The apparatus of claim 1 wherein a logical path between a system memory end and a mass storage end of a transfer comprises at least one of:
circuitry to convert cache lines into a sector or
circuitry to convert a sector into cache lines.

8. The apparatus of claim 1 wherein the non volatile memory interface, the system memory storage logic and the DMA circuitry are part of a computing system that further comprises one or more of a network interface, display, or a battery.

9. The apparatus of claim 8 wherein the non volatile memory interface comprises one of:
a system memory interface or
a mass storage interface.

10. The apparatus of claim 1 wherein said system memory comprises battery backed up DRAM.

11. The apparatus of claim 8 wherein said system memory storage logic comprises circuitry to mimic a mass storage device.

12. A method, comprising:
a) determining whether a transfer of data between a system memory and a mass storage region within a non volatile random access memory is characterized as being one of i) and ii) below:
i) a smaller amount of data to be transferred and/or a high priority transfer;
ii) a larger amount of data to be transferred and/or a low priority transfer; and,
b) processing the transfer with a plurality of CPU cycles akin to a plurality of system memory requests issued from the CPU if the transfer is characterized as i) above, or, processing the transfer with a DMA transfer process if the transfer is characterized as ii) above.

13. The method of claim 12 wherein said mass storage region resides in a non volatile region of said system memory.

14. The method of claim 13 wherein said system memory comprises a multi-level system memory.

15. The method of claim 12 wherein said mass storage region resides in a non volatile random access memory coupled to a mass storage interface.

16. At least one machine readable storage medium containing stored program code that when processed by a computing system cause a method to be performed, said method comprising:
a) recognizing that a transfer of data between a system memory and a mass storage region within a non volatile random access memory is characterized as being one of i) and ii) below:
i) a smaller amount of data to be transferred and/or a high priority transfer;
ii) a larger amount of data to be transferred and/or a low priority transfer; and,
b) processing the transfer with a plurality of CPU cycles akin to a plurality of system memory requests issued from the CPU if the transfer is characterized as i) above, or, processing the transfer with a DMA transfer process if the transfer is characterized as ii) above.

17. The machine readable medium of claim 16 wherein said mass storage region resides in a non volatile region of said system memory.

18. The machine readable medium of claim 17 wherein said system memory comprises a multi-level system memory.

19. The machine readable medium of claim 16 wherein said mass storage region resides in a non volatile random access memory coupled to a mass storage interface.

20. The machine readable medium of claim 16 wherein said method is performed by a mass storage device driver.
